(19) United States
(12) Patent Application Publication
(10) Pub. No.: US 2024/0099145 A1
(43) Pub. Date: Mar. 21, 2024

(54) PIEZOELECTRIC DEVICE AND PREPARATION METHOD THEREFOR, PANEL, AND TACTILE REPRODUCTION APPARATUS

(71) Applicants: BEIJING BOE TECHNOLOGY DEVELOPMENT CO., LTD., Beijing (CN); BOE Technology Group Co., Ltd., Beijing (CN)

(72) Inventors: Hui Hua, Beijing (CN); Yuju Chen, Beijing (CN); Xiaotong Liu, Beijing (CN); Yongchun Tao, Beijing (CN)

(73) Assignees: BEIJING BOE TECHNOLOGY DEVELOPMENT CO., LTD., Beijing (CN); BOE Technology Group Co., Ltd., Beijing (CN)

(21) Appl. No.: 18/274,229

(22) PCT Filed: Jul. 1, 2022
(86) PCT No.: PCT/CN2022/103456

§ 371 Date: Jul. 26, 2023

(30) Foreign Application Priority Data
Jul. 20, 2021 (CN) 202110818210.1

(51) Int. Cl. H10N 30/87; B06B 1/06; G08B 6/00; H10N 30/06; H10N 30/082

(52) U.S. Cl. CPC H10N 30/875; B06B 1/0622; B06B 1/0648; G08B 6/00; H10N 30/06; H10N 30/082

(57) ABSTRACT

The present disclosure provides a piezoelectric device and a preparation method therefor, a panel, and a tactile reproduction apparatus. The piezoelectric device includes: a substrate; a bottom electrode layer disposed on the substrate; a piezoelectric functional layer disposed on the bottom electrode layer; a top electrode layer disposed on the piezoelectric functional layer; an insulation layer, arranged to cover an edge portion of the top electrode layer, the piezoelectric functional layer exposed from the top electrode layer and the bottom electrode layer exposed from the piezoelectric functional layer, an edge of the insulation layer has a slope angle less than 60 degrees; and a wiring layer disposed on the insulation layer, the wiring layer at least partially covers the top electrode layer exposed from the insulation layer, and the wiring layer covers the edge of the insulation layer in an overlapping area of the wiring layer and the insulation layer.

### CROSS-REFERENCE TO RELATED APPLICATION

This application is a national phase application under 35 U.S.C. § 371 of International Patent Application No. PCT/CN2022/103456 filed on Jul. 1, 2022, which claims priority to Chinese patent application No. 202110818210.1, titled “PIEZOELECTRIC DEVICE AND PREPARATION METHOD THEREFOR, PANEL, AND TACTILE REPRODUCTION APPARATUS” submitted to China National Intellectual Property Administration on Jul. 20, 2021, the entire contents of which are incorporated herein by reference.

### TECHNICAL FIELD

The present disclosure relates to the field of electronic technology, in particular to a piezoelectric device, a preparation method for the same, a panel, and a tactile reproduction apparatus.

### BACKGROUND

In recent years, the tactile reproduction technology has been more and more widely used in the fields of human-computer interaction and virtual reality. Tactile reproduction has broad application prospects in the fields of education for the blind and telemedicine. With the gradual maturity of technology, tactile reproduction will be more applied to public life.

Piezoelectric devices may be used as tactile reproduction devices, and the surface friction is adjusted through the resonance generated by the piezoelectric functional layer and the glass substrate, thereby realizing the texture reproduction of objects on the glass surface.

### SUMMARY

The present disclosure provides a piezoelectric device, including:
a substrate;
a bottom electrode layer disposed on the substrate;
a piezoelectric functional layer disposed on the bottom electrode layer;
a top electrode layer disposed on the piezoelectric functional layer;
an insulation layer, the insulation layer is arranged to cover an edge portion of the top electrode layer, and cover the piezoelectric functional layer exposed from the top electrode layer and the bottom electrode layer exposed from the piezoelectric functional layer, an edge of the insulation layer has a slope angle, and the slope angle is less than 60 degrees;
a wiring layer disposed on the insulation layer, the wiring layer at least partially covers the top electrode layer exposed from the insulation layer, and the wiring layer covers the edge of the insulation layer in an overlapping area of the wiring layer and the insulation layer.

Optionally, the slope angle is greater than 30 degrees.

Optionally, in a direction perpendicular to the substrate, a thickness of the insulation layer is greater than a thickness of the piezoelectric functional layer.

Optionally, the piezoelectric device also includes:
a signal terminal portion disposed on the substrate, the signal terminal portion is arranged in the same layer as the bottom electrode layer, the insulation layer partially covers the signal terminal portion, and the wiring layer partially covers the signal terminal end.

Optionally, a material of the insulation layer is a negative photoresist.

Optionally, the piezoelectric functional layer includes a plurality of discrete piezoelectric functional blocks.

The present disclosure also provides a method for preparing a piezoelectric device, including:
providing a substrate;
forming a bottom electrode base layer, a piezoelectric functional base layer and a top electrode base layer stacked on the substrate in sequence;
patterning the top electrode base layer, the piezoelectric functional base layer and the bottom electrode base layer in sequence, and obtaining a bottom electrode layer formed on the substrate, a piezoelectric functional layer formed on the bottom electrode layer, and a top electrode layer formed on the piezoelectric functional layer;
forming an insulation base layer through a spin coating process; the rotation speed of the spin coating process is greater than or equal to 350 rpm and less than or equal to 450 rpm;
patterning the insulation base layer to obtain an insulation layer, the insulation layer is arranged to cover an edge portion of the top electrode layer, and cover the piezoelectric functional layer exposed from the top electrode layer and the bottom electrode layer exposed from the piezoelectric functional layer; an edge of the insulation layer has a slope angle, and the slope angle is less than 60 degrees; and
forming a wiring layer on the insulation layer, the wiring layer at least partially covers the top electrode layer exposed from the insulation layer, and the wiring layer covers the edge of the insulation layer in an overlapping area of the wiring layer and the insulation layer.

Optionally, the slope angle is greater than 30 degrees.

Optionally, a material of the insulation layer is a negative photoresist.

Optionally, the patterning the insulation base layer to obtain an insulation layer includes:
exposing the insulation base layer through a mask; and
obtaining the insulation layer by developing the insulation base layer being exposed.

Optionally, before forming an insulation base layer through a spin coating process, the method further includes:
forming a signal terminal portion on the substrate, the signal terminal portion is arranged on the substrate in the same layer as the bottom electrode layer, the insulation layer partially covers the signal terminal portion, and the wiring layer partially covers the signal terminal portion.

The present disclosure also provides a panel including the above-mentioned piezoelectric device.

The present disclosure also provides a tactile reproduction apparatus including the above-mentioned panel.

The above-mentioned description is merely an overview of the technical solutions of the present disclosure. In order to know about the technical means of the present disclosure more clearly and implement the solutions according to the contents of the specification, and in order to make the above-mentioned and other objects, features and advantages of the present disclosure more apparent and understandable, specific implementations of the present disclosure are set forth below

### BRIEF DESCRIPTION OF THE DRAWINGS

In order to describe the embodiments of the present disclosure or the technical solutions in the related art more clearly, the accompanying drawings which are used in the description of the embodiments or the related art will be briefly introduced. Apparently, the accompanying drawings in the following description are some embodiments of the present disclosure, and those skilled in the art may obtain other accompanying drawings according to these accompanying drawings without paying any creative effort.

FIG. 1 is a schematic cross-sectional view of a piezoelectric device according to an embodiment of the present disclosure;

FIG. 2 is a schematic top view of a partial structure of a piezoelectric device according to an embodiment of the present disclosure;

FIG. 3 is a schematic top view of a partial structure of another piezoelectric device according to an embodiment of the present disclosure;

FIG. 4 is a schematic top view of a partial structure of yet another piezoelectric device according to an embodiment of the present disclosure;

FIG. 5 is a schematic top view of a piezoelectric functional layer according to an embodiment of the present disclosure;

FIG. 6 is a schematic cross-sectional view of an edge of an insulation layer according to an embodiment of the present disclosure; and

FIG. 7 is a flow chart illustrating steps of a method for preparing a piezoelectric device according to an embodiment of the present disclosure.

### DETAILED DESCRIPTION OF THE EMBODIMENTS

In order to make the objects, technical solutions and advantages of the embodiments of the present disclosure clearer, the technical solutions in the embodiments of the present disclosure will be clearly and thoroughly described below in conjunction with the drawings in the embodiments of the present disclosure. Apparently, the described embodiments are some of the embodiments of the present disclosure, rather than all the embodiments. All other embodiments obtained, based on the embodiments in the present disclosure, by those skilled in the art without paying creative efforts fall within the protection scope of the present disclosure.

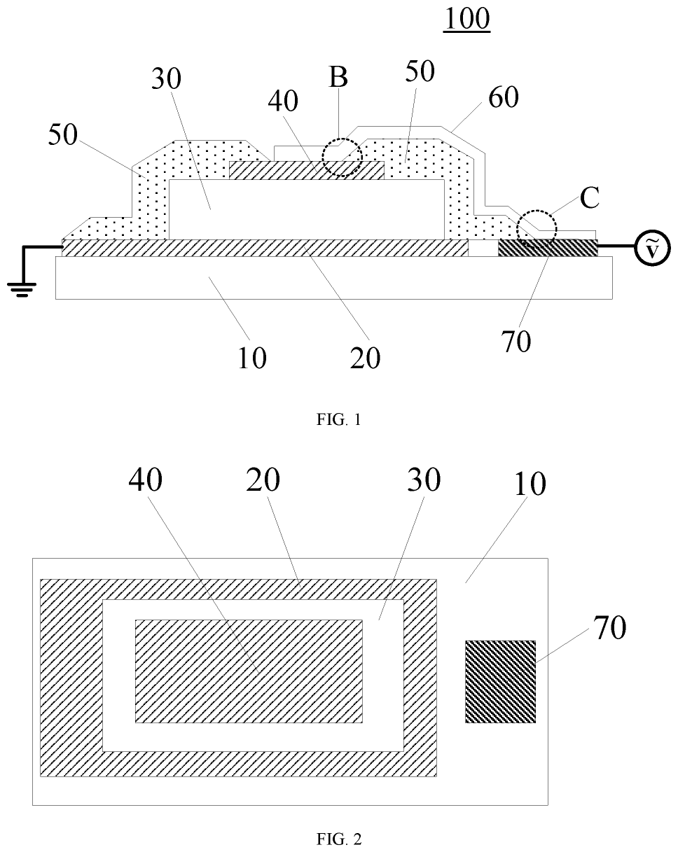

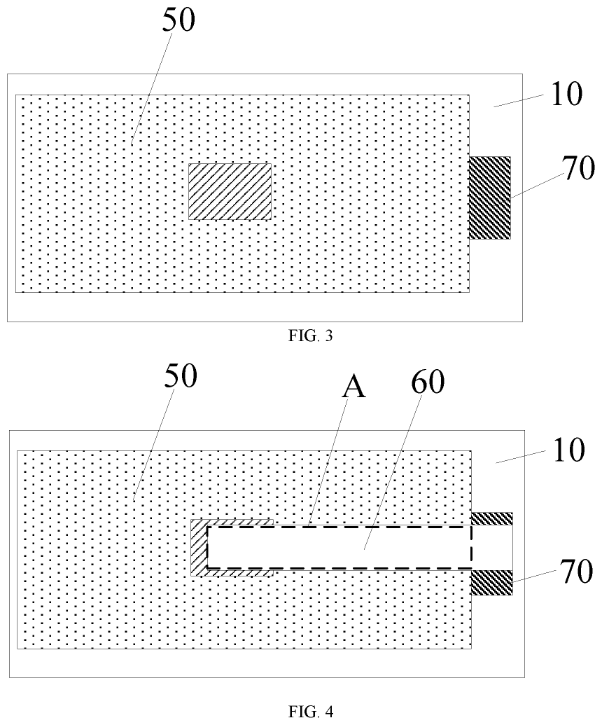

FIG. 1 is a schematic cross-sectional view of a piezoelectric device according to an embodiment of the present disclosure; FIG. 2 is a schematic top view of a partial structure of a piezoelectric device according to an embodiment of the present disclosure; FIG. 3 is a schematic top view of a partial structure of another piezoelectric device according to an embodiment of the present disclosure; FIG. 4 is a schematic top view of a partial structure of yet another piezoelectric device according to an embodiment of the present disclosure. Referring to FIG. 1 and FIG. 2, the piezoelectric device 100 includes:
a substrate 10;
a bottom electrode layer 20 disposed on the substrate 10;
a piezoelectric functional layer 30 disposed on the bottom electrode layer 20;
a top electrode layer 40 disposed on the piezoelectric functional layer 30;
an insulation layer 50; and
a wiring layer 60 disposed on the insulation layer 50.

Referring to FIG. 3, the insulation layer 50 is arranged to cover an edge portion of the top electrode layer 40, and cover the piezoelectric functional layer 30 exposed from the top electrode layer 40 and the bottom electrode layer 20 exposed from the piezoelectric functional layer 30. The edge of the insulation layer 50 has a slope angle less than 60 degrees.

Referring to FIG. 4, the wiring layer 60 is arranged to at least partially cover the top electrode layer 40 exposed from the insulation layers 50, and the wiring layer 60 covers the edge of the insulation layer 50 in an overlapping area A of the wiring layer 60 and the insulation layer 50.

Optionally, the substrate 10 may be made of glass materials.

Optionally, the material of the piezoelectric functional layer 30 may be PZT (lead zirconate titanate piezoelectric ceramic), LiNbO3 (lithium niobate), AlN (aluminum nitride) or ZnO (zinc oxide). Among them, PZT can produce larger strain due to a larger piezoelectric constant.

In practical applications, the bottom electrode layer 20 may be grounded, and an alternating electric field of a specific frequency may be applied to the top electrode layer 40, so as to energize the piezoelectric functional layer 30 and the glass substrate to generate resonance.

Further, the insulation layer 50 covers the edge portion of the top electrode layer 40, so that the current density at the contact portion between the wiring layer 60 and the top electrode layer 40 is reduced, thereby solving the problem of a short service life of the piezoelectric device caused by excessive local current density, and improving the reliability of the piezoelectric device.

FIG. 5 is a schematic top view of the piezoelectric functional layer 30 according to an embodiment of the present disclosure. Referring to FIG. 5, optionally, the piezoelectric functional layer 30 includes a plurality of discrete piezoelectric functional blocks 301. The piezoelectric functional layer 30 of the piezoelectric device 100 may be designed in blocks, for example, the piezoelectric functional layer 30 may be designed as a plurality of discrete rectangular piezoelectric functional blocks 301. In this way, it is possible to avoid integral failure of the piezoelectric device 100 caused by the short circuit at an individual part of the piezoelectric functional layer 30.

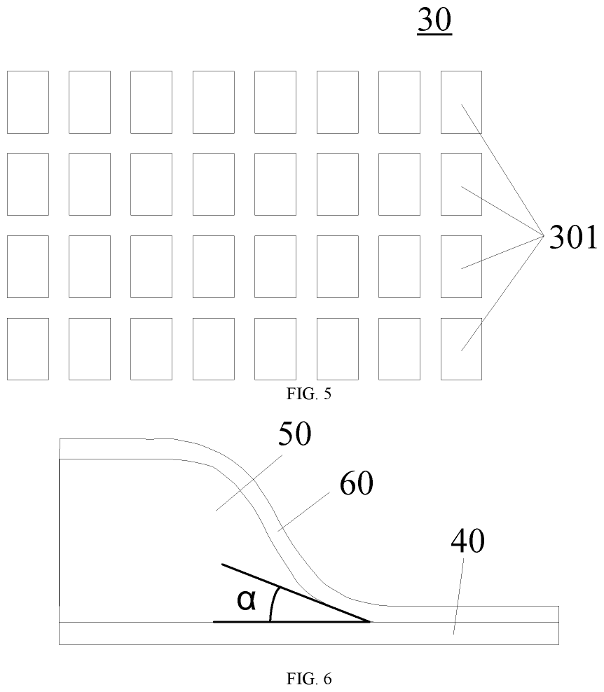

FIG. 6 is a schematic cross-sectional view of an edge of the insulation layer 50 according to an embodiment of the present disclosure. Referring to FIG. 6, the edge of the insulation layer 50 has an epitaxial morphology with a certain slope. The edge of the insulation layer 50 has a slope angle α, where the slope angle α is less than 60 degrees.

For the piezoelectric device, the lower film layers required to be covered by the insulation layer are relatively thick, among them, only the thickness of the piezoelectric functional layer 30 may reach the micron level. In a common implementation, the thickness of the piezoelectric functional layer 30 may be 2 μm. For such a device, it is necessary to provide a thicker insulation layer, usually more than 2 μm. Therefore, the wiring layer above the insulation layer needs to climb a large height at the edge of the insulation layer. However, since the edge of the insulation layer has a large slope, the local segment difference is large. The wiring layer is prone to breakage at the edge of the insulation layer when climbing along the edge of the insulation, so that the device cannot be energized by the signal, resulting in the overall failure of the device.

For example, in areas B and C in FIG. 1, the wiring layer 60 climbs along the edge of the insulation layer 50. Accordingly, the wiring layer 60 is prone to breakage in areas B and C.

On the contrary, in the embodiment of the present disclosure, in an overlapping area A of the wiring layer 60 and the insulation layer 50, the wiring layer 60 covers the edge of the insulation layer 50. Since the slope angle α of the edge of the insulation layer 50 is less than 60 degrees, the wiring layer 60 is not prone to breakage at the edge of the insulation layer 50 when climbing along the edge of the insulation layer 50, which reduces the risk of overall failure of the piezoelectric device 100.

Optionally, the slope angle α may also be greater than 30 degrees. That is, the slope angle α of the edge of the insulation layer is greater than 30 degrees and less than 60 degrees. In practical applications, since the insulation layer 50 of the piezoelectric device 100 is generally thicker, the slope angle α of the edge of the insulation layer should not be set too small, and can be greater than 30 degrees. If the slope angle α is too small, the climbing distance of the wiring layer 60 will be increased.

Optionally, the bottom electrode layer 20, the top electrode layer 40 and the wiring layer 60 may be made of metal materials such as Au, Cu, Al, AlNd, Mo, Pt, Ti or Ni, or metal oxide materials with high transparency, such as Sn-doped In2O3 (ITO), Zn-doped In2O3 (IZO), and Ga-doped ZnO (GZO). By preparing the bottom electrode layer 20, the top electrode layer 40 and the wiring layer 60 using transparent electrode materials, the overall transmittance of the piezoelectric device 100 can be improved, and the average transmittance can reach more than 75%.

Optionally, in a direction perpendicular to the substrate 10, the thickness of the insulation layer 50 is greater than the thickness of the piezoelectric functional layer 30.

For example, in a specific implementation mode, the thickness of the piezoelectric functional layer 30 in the direction perpendicular to the substrate 10 is 2 μm, and the thickness of the insulation layer 50 in the direction perpendicular to the substrate 10 may be 3.5 μm.

Optionally, referring to FIG. 1, the piezoelectric device 100 further includes a signal terminal portion 70 disposed on the substrate 10. The signal terminal portion 70 and the bottom electrode layer 20 are arranged in the same layer, the insulation layer 50 partially covers the signal terminal portion 70, and the wiring layer 60 partially covers the signal terminal portion 70.

The signal terminal portion 70 may specifically be a pad. The wiring layer 60 is connected to the signal terminal portion 70, so that the AC electric field signal of a specific frequency may be transferred to the wiring layer 60 through the signal terminal portion 70, and then transferred to the top electrode layer 40 through the wiring layer 60, thereby realizing signal excitation control of resonance.

Optionally, the material of the insulation layer 50 may be a negative photoresist.

In a specific implementation mode, the material of the insulation layer 50 may be a negative photoresist having a model of SOC-5004U.

In the process of implementing the embodiments of the present disclosure, the inventor has also selected two other materials as the materials of the insulation layer to prepare the piezoelectric device. One material is a photoresist with a model of SU8, and the other material is a photoresist with a model of DL-1000-C. Moreover, the inventor has also used a scanning electron microscope (SEM) to characterize morphology of a piezoelectric device using SU8 photoresist as the insulation layer material (hereinafter referred to as sample 1), morphology of a piezoelectric device using the DL-1000-C photoresist as the insulation layer material (hereinafter referred to as sample 2), and morphology of a piezoelectric device using SOC-5004U photoresist as the insulating layer material (hereinafter referred to as sample 3).

In sample 1, the thickness of the insulation layer 50 is 4.76 microns, an inset chamfer is generated at the edge of the insulation layer 50 near the underlying film layer, and there is no smooth transition slope. The wiring layer 60 breaks at the edge of the insulation layer 50.

In sample 2, the thickness of the insulation layer 50 is 3.17 microns, the slope angle α at the edge of the insulation layer 50 is greater than 60 degrees, and the wiring layer 60 breaks at the climbing position of the edge of the insulation layer 50.

In sample 3, the thickness of the insulation layer 50 is 2.69 micrometers, the thickness of the wiring layer 60 is 289 nm, the thickness of the top electrode layer 40 is 234 nm, the thickness of the piezoelectric functional layer 30 is 2.07 μm, and the thickness of the bottom electrode layer 20 is 523 nm. In sample 3, the slope angle α at the edge of the insulation layer 50 is less than 60 degrees, and the wiring layer 60 does not break at the climbing position of the edge of the insulation layer 50.

In addition, the piezoelectric device 100 may also include conventional structures such as an encapsulation layer, which is not specifically limited in the embodiment of the present disclosure.

It should be noted that the embodiments of the present disclosure provide some schematic drawings for further understanding of the present disclosure. It should be understood that these schematic drawings for explaining the present disclosure are not intended to limit the present disclosure.

In the embodiment of the present disclosure, the piezoelectric device includes a substrate, a bottom electrode layer disposed on the substrate, a piezoelectric functional layer disposed on the bottom electrode layer, a top electrode layer disposed on the piezoelectric functional layer, an insulation layer, and a wiring layer disposed on the insulation layer. The insulation layer is arranged to cover an edge portion of the top electrode layer, and cover the piezoelectric functional layer exposed from the top electrode layer and the bottom electrode layer exposed from the piezoelectric functional layer. The edge of the insulation layer has a slope angle less than 60 degrees. The wiring layer at least partially covers the top electrode layer exposed from the insulation layer, and the wiring layer covers the edge of the insulation layer in the overlapping area of the wiring layer and the insulation layer. In the embodiment of the present disclosure, the piezoelectric device has a relatively large slope at the edge of the insulation layer, and the local segment difference is relatively large. Therefore, the wiring layer can be prevented from breaking at the edge of the insulation layer by controlling the slope angle at the edge of the insulation layer to be less than 60 degrees, and the risk of overall failure of the piezoelectric device is reduced.

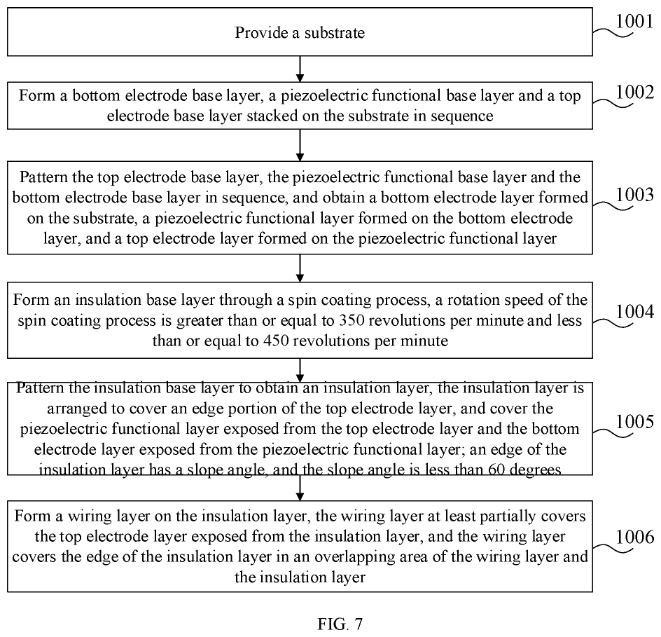

FIG. 7 is a flow chart of steps of a method for preparing a piezoelectric device according to an embodiment of the present disclosure. With reference to FIG. 7, the method includes the following steps.

At step 1001, a substrate is provided.

Optionally, the substrate may be made of glass materials.

At step 1002, a bottom electrode base layer, a piezoelectric functional base layer and a top electrode base layer are stacked on the substrate in sequence.

Optionally, the bottom electrode base layer may be formed on the substrate through a deposition process.

Optionally, the piezoelectric functional base layer may be formed on the bottom electrode base layer through a sol-gel process or a magnetron sputtering process.

Optionally, the top electrode base layer may be formed on the piezoelectric functional base layer through a deposition process.

Optionally, the bottom electrode base layer and the top electrode base layer may be made of metal materials such as Au, Cu, Al, AlNd, Mo, Pt, Ti or Ni, or metal oxide materials with high transparency.

Optionally, the material of the piezoelectric functional base layer may be PZT, LiNbO3, AlN or ZnO. Among them, PZT can produce larger strain due to a larger piezoelectric constant.

At step 1003, the top electrode base layer, the piezoelectric functional base layer and the bottom electrode base layer are patterned in sequence, so as to obtain a bottom electrode layer formed on the substrate, a piezoelectric functional layer formed on the bottom electrode layer, and a top electrode layer formed on the piezoelectric functional layer.

Specifically, the patterning treatment on the top electrode base layer may include sub-steps of photoresist coating, photolithography, development, etching and stripping of photoresist. The sub-step of etching may be wet etching or dry etching IBE (ion beam etching).

The patterning treatment on the piezoelectric functional base layer may specifically include sub-steps of photoresist coating, photolithography, development, etching and stripping of photoresist.

The patterning treatment on the bottom electrode base layer may specifically include sub-steps of photoresist coating, photolithography, development, etching and stripping of photoresist. The etching sub-step may be wet etching or IBE dry etching.

At step 1004, an insulation base layer is formed through a spin coating process. The rotation speed of the spin coating process is greater than or equal to 350 rpm (revolutions per minute) and less than or equal to 450 rpm.

In the usual technology, the rotation speed of the spin coating process for preparing film layers is usually controlled at 20004000 rpm. However, the piezoelectric device requires a thicker insulation layer, and the rotation speed of the spin coating process is too fast, resulting in a slope angle greater than 60 degrees. As a result, the wiring layer above the insulation layer is prone to breakage. Therefore, the rotation speed of the spin coating process for forming the insulation layer may be controlled to be within a low speed range of 350450 revolutions per minute in the embodiment of the present disclosure, so that the edge of the insulation layer may be an epitaxial morphology with a certain slope, and a slope angle may be controlled to be within a range of less than 60 degrees. In this way, the wiring layer is less likely to be broken at the edge of the insulation layer, reducing the risk of overall failure of the piezoelectric device.

Optionally, the material of the insulation layer may be a negative photoresist, such as SOC-5004U photoresist.

At step 1005, the insulation base layer is patterned to obtain an insulation layer. The insulation layer is arranged to cover an edge portion of the top electrode layer, and cover the piezoelectric functional layer exposed from the top electrode layer and the bottom electrode layer exposed from the piezoelectric functional layer. The edge of the insulation layer has a slope angle less than 60 degrees.

Optionally, in the case where the material of the insulation layer is a negative photoresist, step 1005 may specifically include the following steps:
exposing the insulation base layer through a mask; and
developing the exposed insulation base layer to obtain the insulation layer.

Since the material of the insulation layer is photoresist, the patterning of the insulation base layer can be realized through exposure and development, so that part of the top electrode layer is exposed from the insulation base layer.

In an optional specific implementation manner, the insulation layer may be prepared by using SOC-5004U photoresist. First of all, the pre-rotation speed of the spin coating process may be 300 rpm, the official rotation rate may be 350 rpm, so that the thickness of the prepared insulation base layer is about 3.5 microns. After the insulation base layer is patterned, the insulation layer is obtained. The insulation layer may exactly cover the step of the piezoelectric functional layer with a thickness of 2 μm, and the edge of the insulation layer can maintain a slope angle less than 45°.

Optionally, the slope angle may be greater than 30 degrees. That is, the slope angle of the edge of the insulation layer is greater than 30 degrees and less than 60 degrees. In practical applications, since the insulation layer of the piezoelectric device is generally thicker, the slope angle at the edge of the insulation layer should not be set too small, and can be greater than 30 degrees. If the slope angle is too small, the climbing distance of the wiring layer will be increased.

At step 1006, a wiring layer is formed on the insulation layer. The wiring layer at least partially covers the top electrode layer exposed from the insulation layer, and the wiring layer covers the edge of the insulation layer in the overlapping area of the wiring layer and the insulation layer.

Optionally, the wiring layer may be formed on the insulation layer through a lift-off (stripping) process. In a specific implementation, the photoresist may be deposited on the insulation layer first, then the development is performed according to the preset position of the wiring layer, and then a metal film layer is deposited, and then the photoresist is removed with acetone to obtain the wiring layer made from metal materials.

In the embodiment of the present disclosure, in the overlapping area of the wiring layer and the insulation layer, the wiring layer covers the edge of the insulation layer. Since the slope angle at the edge of the insulation layer is less than 60 degrees, the wiring layer is not prone to breakage at the edge of the insulation layer when climbing along the edge of the insulation layer, which reduces the risk of overall failure of the piezoelectric device.

Optionally, before step 1004, the manufacturing method may further include the following steps:
forming a signal terminal portion on the substrate, the signal terminal portion being arranged in the same layer as the bottom electrode layer, the insulation layer partially covering the signal terminal portion, and the wiring layer partially covering the signal terminal portion.

The signal terminal portion may specifically be a pad. The wiring layer is connected to the signal terminal portion, so that the AC electric field signal of a specific frequency may be transferred to the wiring layer through the signal terminal portion, and then transferred to the top electrode layer through the wiring layer, thereby realizing signal excitation control of resonance.

The embodiment of the present disclosure does not limit the formation sequence of the signal terminal portion and the bottom electrode layer.

In addition, the manufacturing method may also include conventional steps such as forming an encapsulation layer, which is not specifically limited in the embodiments of the present disclosure.

In the embodiment of the present disclosure, after preparing, on the substrate, the bottom electrode layer formed on the substrate, the piezoelectric functional layer formed on the bottom electrode layer, and the top electrode layer formed on the piezoelectric functional layer, an insulation base layer is formed through a spin coating process. The rotation speed of the spin coating process is greater than or equal to 350 revolutions per minute and less than or equal to 450 revolutions per minute. Then, the insulation base layer is patterned to obtain an insulation layer. The insulation layer covers the edge portion of the top electrode layer, and covers the piezoelectric functional layer exposed from the top electrode layer and the bottom electrode layer exposed from the piezoelectric functional layer. The edge of the insulation layer has a slope angle less than 60 degrees. Next, the wiring layer is formed on the insulation layer. In the embodiment of the present disclosure, the rotation speed of the spin coating process for forming the insulation layer may be controlled to be within a low speed range of 350˜450 revolutions per minute, so that the edge of the insulation layer may be an epitaxial morphology with a certain slope, and a slope angle may be controlled to be within a range of less than 60 degrees. In this way, the wiring layer is less likely to be broken at the edge of the insulation layer, reducing the risk of overall failure of the piezoelectric device.

An embodiment of the present disclosure also provides a panel including the above-mentioned piezoelectric device.

Optionally, piezoelectric devices may be arranged according to the realization requirements of tactile reproduction.

In the embodiment of the present disclosure, the piezoelectric device includes a substrate, a bottom electrode layer disposed on the substrate, a piezoelectric functional layer disposed on the bottom electrode layer, a top electrode layer disposed on the piezoelectric functional layer, an insulation layer, and a wiring layer disposed on the insulation layer. The insulation layer is arranged to cover an edge portion of the top electrode layer, and cover the piezoelectric functional layer exposed from the top electrode layer and the bottom electrode layer exposed from the piezoelectric functional layer. The edge of the insulation layer has a slope angle less than 60 degrees. The wiring layer at least partially covers the top electrode layer exposed from the insulation layer, and the wiring layer covers the edge of the insulation layer in the overlapping area of the wiring layer and the insulation layer. In the embodiment of the present disclosure, the piezoelectric device has a relatively large slope at the edge of the insulation layer, and the local segment difference is relatively large. Therefore, the wiring layer can be prevented from breaking at the edge of the insulation layer by controlling the slope angle at the edge of the insulation layer to be less than 60 degrees, and the risk of overall failure of the piezoelectric device is reduced.

An embodiment of the present disclosure also provides a tactile reproduction apparatus including the above-mentioned panel.

In the embodiment of the present disclosure, the piezoelectric device in the panel includes a substrate, a bottom electrode layer disposed on the substrate, a piezoelectric functional layer disposed on the bottom electrode layer, a top electrode layer disposed on the piezoelectric functional layer, an insulation layer, and a wiring layer disposed on the insulation layer. The insulation layer is arranged to cover an edge portion of the top electrode layer, and cover the piezoelectric functional layer exposed from the top electrode layer and the bottom electrode layer exposed from the piezoelectric functional layer. The edge of the insulation layer has a slope angle less than 60 degrees. The wiring layer at least partially covers the top electrode layer exposed from the insulation layer, and the wiring layer covers the edge of the insulation layer in the overlapping area of the wiring layer and the insulation layer. In the embodiment of the present disclosure, the piezoelectric device has a relatively large slope at the edge of the insulation layer, and the local segment difference is relatively large. Therefore, the wiring layer can be prevented from breaking at the edge of the insulation layer by controlling the slope angle at the edge of the insulation layer to be less than 60 degrees, and the risk of overall failure of the piezoelectric device is reduced.

“one embodiment”, “an embodiment” or “one or more embodiments” as used herein means that a particular feature, structure, or characteristic described in connection with embodiments is included in at least one embodiment of the present disclosure. In addition, please note that examples of the word “in one embodiment” herein do not necessarily all refer to the same embodiment.

In the description provided herein, numerous specific details are set forth. However, it is understood that embodiments of the present disclosure may be practiced without these specific details. In some instances, well-known methods, structures and techniques have not been shown in detail in order not to obscure the understanding of this description.

In the claims, any reference signs placed between parentheses shall not be construed as limiting the claim. The word “comprising” does not exclude the presence of elements or steps not listed in the claim. The word “a” or “an” preceding an element does not exclude the presence of a plurality of such elements. The disclosure may be implemented by means of hardware including several distinct elements and a suitably programmed computer. In a unit claim enumerating several devices, several of these devices may be embodied by the same hardware item. The words such as “first”, “second”, and “third” as used not indicate any order. These words may be interpreted as names.

Finally, it should be noted that the above embodiments are only used to illustrate the technical solutions of the present disclosure, rather than limiting them. Although the present disclosure has been described in detail with reference to the foregoing embodiments, those skilled in the art should understand that: the technical solutions described in the foregoing embodiments can still be modified, or equivalent replacements for some of the technical features may be performed; and these modification or replacement does not make the essence of the corresponding technical solutions deviate from the spirit and scope of the technical solutions of the embodiments of the present disclosure.

1. A piezoelectric device, comprising:
a substrate;
a bottom electrode layer disposed on the substrate;
a piezoelectric functional layer disposed on the bottom electrode layer;
a top electrode layer disposed on the piezoelectric functional layer;
an insulation layer, wherein the insulation layer is arranged to cover an edge portion of the top electrode layer, and cover the piezoelectric functional layer exposed from the top electrode layer and the bottom electrode layer exposed from the piezoelectric functional layer, an edge of the insulation layer has a slope angle, and the slope angle is less than 60 degrees; and
a wiring layer disposed on the insulation layer, wherein the wiring layer at least partially covers the top electrode layer exposed from the insulation layer, and the wiring layer covers the edge of the insulation layer in an overlapping area of the wiring layer and the insulation layer.

2. The piezoelectric device according to claim 1, wherein the slope angle is greater than 30 degrees.

3. The piezoelectric device according to claim 1, wherein, in a direction perpendicular to the substrate, a thickness of the insulation layer is greater than a thickness of the piezoelectric functional layer.

4. The piezoelectric device according to claim 1, further comprising:
a signal terminal portion disposed on the substrate, wherein the signal terminal portion is arranged in the same layer as the bottom electrode layer, the insulation layer partially covers the signal terminal portion, and the wiring layer partially covers the signal terminal portion.

5. The piezoelectric device according to claim 1, wherein a material of the insulation layer is a negative photoresist.

6. The piezoelectric device according to claim 1, wherein the piezoelectric functional layer comprises a plurality of discrete piezoelectric functional blocks.

7. A method for preparing a piezoelectric device, comprising:
providing a substrate;
forming a bottom electrode base layer, a piezoelectric functional base layer and a top electrode base layer stacked on the substrate in sequence;
patterning the top electrode base layer, the piezoelectric functional base layer and the bottom electrode base layer in sequence, and obtaining a bottom electrode layer formed on the substrate, a piezoelectric functional layer formed on the bottom electrode layer, and a top electrode layer formed on the piezoelectric functional layer;
forming an insulation base layer through a spin coating process, wherein a rotation speed of the spin coating process is greater than or equal to 350 revolutions per minute and less than or equal to 450 revolutions per minute;
patterning the insulation base layer to obtain an insulation layer, wherein the insulation layer is arranged to cover an edge portion of the top electrode layer, and cover the piezoelectric functional layer exposed from the top electrode layer and the bottom electrode layer exposed from the piezoelectric functional layer; an edge of the insulation layer has a slope angle, and the slope angle is less than 60 degrees; and
forming a wiring layer on the insulation layer, wherein the wiring layer at least partially covers the top electrode layer exposed from the insulation layer, and the wiring layer covers the edge of the insulation layer in an overlapping area of the wiring layer and the insulation layer.

8. The method according to claim 7, wherein the slope angle is greater than 30 degrees.

9. The method according to claim 7, wherein a material of the insulation layer is a negative photoresist.

10. The method according to claim 9, wherein the patterning the insulation base layer to obtain an insulation layer comprises:
exposing the insulation base layer through a mask; and
obtaining the insulation layer by developing the insulation base layer being exposed.

11. The method according to claim 7, wherein before forming an insulation base layer through a spin coating process, the method further comprises:
forming a signal terminal portion on the substrate, wherein the signal terminal portion is arranged on the substrate in the same layer as the bottom electrode layer, the insulation layer partially covers the signal terminal portion, and the wiring layer partially covers the signal terminal portion.

12. A panel comprising a piezoelectric device, wherein the piezoelectric device comprises:
a substrate;
a bottom electrode layer disposed on the substrate;
a piezoelectric functional layer disposed on the bottom electrode layer;
a top electrode layer disposed on the piezoelectric functional layer;
an insulation layer, wherein the insulation layer is arranged to cover an edge portion of the top electrode layer, and cover the piezoelectric functional layer exposed from the top electrode layer and the bottom electrode layer exposed from the piezoelectric functional layer, an edge of the insulation layer has a slope angle, and the slope angle is less than 60 degrees; and
a wiring layer disposed on the insulation layer, wherein the wiring layer at least partially covers the top electrode layer exposed from the insulation layer, and the wiring layer covers the edge of the insulation layer in an overlapping area of the wiring layer and the insulation layer.

13. A tactile reproduction apparatus comprising the panel according to claim 12.
